(19) United States
(12) Patent Application Publication
(10) Pub. No.: US 2007/0040247 A1
(43) Pub. Date: Feb. 22, 2007

(54) Leadframe package with dual lead configurations

(75) Inventors: Jong-Joo Lee, Suwon-si (KR); Mee-Hyun Ahn, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/503,269

(22) Filed: Aug. 14, 2006

Related U.S. Application Data
(63) Continuation-in-part of application No. 11/261,569, filed on Oct. 31, 2005.

(30) Foreign Application Priority Data
Aug. 22, 2005 (KR) 2005-76996

(51) Int. Cl. H01L 23/495

(52) U.S. Cl. 257/666

(57) ABSTRACT

The invention provides a variety of leadframe packages in which signal connections and fixed voltage connections are configured differently to improve the relative performance of the connections relative to their assigned function. The signal connections incorporate one or more configurations of signal lead and corresponding signal bonding wires that tend to reduce the relative capacitance of the signal connectors and thereby improve high speed performance. The fixed voltage connections incorporate configurations of fixed voltage leads and fixed voltage bonding wires that will tend to reduce the inductance of the fixed voltage connector and reduce noise on the fixed voltage connections and improve power delivery characteristics. The configurations of the associated signal and fixed voltage connections will tend to result in signal connections that include signal leads that are shorter, narrower and/or more widely separated from the active surface of the semiconductor chip than the corresponding fixed voltage leads.

### PRIORITY STATEMENT

This U.S. non-provisional application claims priority under 35 U.S.C.§ 119 from Korean Patent Application No. 2005-76996, which was filed on Aug. 22, 2005, the contents of which are incorporated herein, in its entirety, by reference, and is a continuation-in-part of U.S. patent application Ser. No. 11/261,569, filed Oct. 31, 2005, which claims priority under 35 U.S.C. § 119 from Korean Patent Application No. 2004-92447, which was filed on Nov. 12, 2004, the contents of both of which are incorporated herein, in their entirety, by reference.

### BACKGROUND OF THE INVENTION

1. Field of the Invention

The present invention relates to a semiconductor package technology and, more particularly, to leadframe packages having dual lead configurations in which the signal leads and the fixed voltage leads are configured differently.

2. Description of the Related Art

A leadframe packages having a lead-on-chip (LOC) type configuration have been used widely as for packaging lower speed and lower price semiconductor chips including, for example, memory chips having center pads and relatively low pin counts. However, more recent packaging trends have tended to move away from LOC packages and toward area array type packages including, for example, ball grid array (BGA) packages, to provide performance more suitable for higher speed semiconductor products. Other products, even those that do not utilize relatively high pin counts, for example, memory chips, have tended to follow this same trend.

LOC packages can provide certain advantages, for example, reductions in package size and/or lower production costs, because they utilize a relatively inexpensive leadframe. LOC packages also tend to exhibit certain limitations, particularly when used with higher speed devices, that have contributed to the increasing use of BGA packages. In particular, the construction of an LOC package in which elongated leads are disposed above an active surface of a semiconductor chip results in parasitic capacitance. Increasing levels of parasitic capacitance, induced between the signal leads and the active surface of the semiconductor chip in an LOC package, tends to degrade the signal delivery and overall performance characteristics of the semiconductor chip. With regard to the fixed voltage leads provided in an LOC package, e.g., power and ground leads, the noise tends to increase as a result of the inductance effects associated with high speed operation of a semiconductor chip.

FIG. 1A is a plan view of a leadframe package 100 according to conventional art. FIG. 1B is a sectional view of FIG. 1A taken along the line IB-IB. A conventional package configuration 100, as illustrated in FIGS. 1A and 1B, is a typical LOC package in which leads 120 are disposed above a semiconductor chip 110.

As illustrated in FIGS. 1A and 1B, the leads 120 disposed above the active surface of the semiconductor chip 110 are attached to the active surface of the semiconductor chip 110 by an adhesive tape 130. A plurality of chip pads 112 are formed in a row in the center of the active surface of the semiconductor chip 110, and the leads 120 are extended towards the chip pads 112. The chip pads 112 are electrically connected to the leads 120 by bonding wires 140. The semiconductor chip 110, leads 120 and bonding wires 140 are sealed by a molding resin 150.

Chip pads 112 may generally be classified as signal pads or fixed voltage pads according to their function. Those pads classified as signal pads tend to include control terminals, address terminals and/or data input/output terminals while those classified as fixed voltage pads are typically limited to the power terminal(s) and ground terminal(s). The classification of the leads 120 and bonding wires 140 typically corresponds to the classification of the chip pads 112 to which the leads and bonding wires are electrically connected.

In the conventional construction illustrated in FIGS. 1A and 1B, the signal leads and fixed voltage leads of a conventional leadframe 100 tend to exhibit little, if any, difference in the configuration. Accordingly, the leads 120 of a conventional leadframe 100 do not exhibit asymmetric construction according to their intended function that will tend to improve the relative performance of the signal and/or fixed voltage leads. For example, signal lead performance may be improved, particularly for high speed operation, by reducing the parasitic capacitance, while the fixed voltage lead performance may be improved by reducing inductance and thereby suppressing noise.

However, the parasitic capacitance of the signal leads will tend to increase for leads 120 disposed above the active surface of the semiconductor chip 110 as the area of the lead 120 is increases and/or the separation distance (i.e., the dielectric thickness) between the lead and the active surface of the semiconductor chip 110 decreases. Additionally, all of the signal leads 120 illustrated in FIG. 1A are structured as single layer delivery lines which will also tend to degrade the high speed performance of such signal leads.

Further, when configured as illustrated in FIG. 1A, the fixed voltage leads 120 will tend to exhibit relatively high inductance. Accordingly, as the speed of the semiconductor chip increases, noise, attributed to, for example, simultaneous switching noise (SSN) increases and the power delivery characteristics deteriorate. This deterioration may be further exacerbated by the central location of the chip pads 112 above the active surface of the semiconductor chip 110.

### SUMMARY OF THE INVENTION

The detailed description provided below discloses combinations of lead frames, bonding wires and bonding pad configurations useful for manufacturing LOC semiconductor device packages in which various lead configurations are utilized for leads dedicated to different functions for improving the intrinsic function and performance of the various leads. Example embodiments of the invention include leadframe packages in which combinations of signal leads exhibiting improved signal delivery characteristics and/or fixed voltage leads exhibiting reduced noise improve the performance of the resulting leadframe packages. Leadframe packages incorporating the lead configurations according to the example embodiments of the invention will tend to exhibit improved high-speed performance.

Example embodiments of the invention provide leadframe packages having a dual lead configuration in which signal leads and fixed voltage leads are configured in a manner that tends to increase the performance differences between the two types of leads. Leadframe packages according to the example embodiments of the invention comprise a semiconductor chip having a plurality of chip pads formed on an active surface, a leadframe including a plurality of signal leads and a plurality of fixed voltage leads configured so that the average length of the signal leads is less than the average length of the fixed voltage leads.

Leadframe packages according to the example embodiments of the invention further comprise a plurality of bonding wires with signal bonding wires electrically connecting each signal lead to the corresponding chip pad and fixed voltage bonding wires electrically connecting each fixed voltage lead to the corresponding chip pad. In example embodiments of leadframe packages according to the invention, the average length of the signal bonding wires will typically be greater than the average length of the fixed voltage bonding wires. In addition to the greater average length, the signal leads will typically exhibit a lower average capacitance, a smaller average area, and a smaller average width relative to the fixed voltage leads.

Example embodiments of leadframe packages according to the invention may included leads configured whereby the sum of the average length of the signal leads and the average length of the signal bonding wires may be less than or equal to the sum of the average length of the fixed voltage leads and the average length of the fixed voltage bonding wires. Example embodiments of leadframe packages according to the invention may include signal leads and/or fixed voltage leads disposed above the active surface of the semiconductor chip and/or at the periphery of the semiconductor chip.

Example embodiments of leadframes according to the invention may have some of both the signal leads and the fixed voltage leads disposed above the active surface of the semiconductor chip while the remaining signal and fixed voltage leads are disposed at the periphery of the semiconductor chip. Other example embodiments of leadframes according to the invention may have all or substantially all of the signal leads disposed at the periphery of the semiconductor chip while all or substantially all the fixed voltage leads include a region that extends over and is disposed above the active surface of the semiconductor chip.

Other example embodiments may incorporate signal bonding wires that extend across and/or above the fixed voltage leads and/or a fixed voltage lead that includes a region extending over the active surface of the semiconductor chip at separation distance that is less than any separation distance maintained between the active surface and the corresponding signal leads. This reduced separation distance may, for example, be formed by bending or otherwise deflecting a region of the fixed voltage lead below the level maintained by the signal leads.

The chip pads may be formed in a row along the center of the active surface of the semiconductor chip, or formed in a row along the edge of the active surface of the semiconductor chip. Alternatively, some of the chip pads may be formed in a row along the center of the active surface of the semiconductor chip, and the remainder may be formed in a row along the edge of the active surface of the semiconductor chip.

In the case that the chip pads are formed in the center of the active surface, all of the signal leads and fixed voltage leads are disposed above the active surface of the semiconductor chip, and may be disposed at both sides of a row of the chip pads. At that time, the average distance between the signal leads and chip pads is preferably greater than that between the fixed voltage leads and chip pads. Additionally, the fixed voltage lead may have an extended width to be placed in the front region of an adjacent signal lead, and the leads having the same potential among the fixed voltage leads may be coupled together.

### BRIEF DESCRIPTION OF THE DRAWINGS

The example embodiments of the invention will be readily understood with reference to the following detailed description thereof provided in conjunction with the accompanying drawings, wherein like reference numerals designate like structural elements.

FIGS. 1A and 1B are respectively a plan view of a leadframe package according to conventional art and a cross-sectional view of the leadframe package of FIG. 1A taken along plane IB-IB;

FIGS. 2A and 2B are respectively a plan view of a leadframe package according to a first example embodiment of the present invention and a cross-sectional view of the leadframe package of FIG. 2A taken along plane IIB-IIB;

FIGS. 3A and 3B are respectively a partial plan view and a cross-sectional view of a leadframe package according to a second example embodiment of the present invention;

FIG. 4 is a sectional view of a leadframe package according to a variation on the second example embodiment of the present invention;

FIGS. 5A and 5B are respectively a plan view and a cross-sectional view of a leadframe package according to a third example embodiment of the present invention;

FIGS. 6A and 6B are respectively a plan view and a cross-sectional view of a leadframe package according to a fourth example embodiment of the present invention; and

FIG. 7 is a plan view of a leadframe package according to a fifth example embodiment of the present invention.

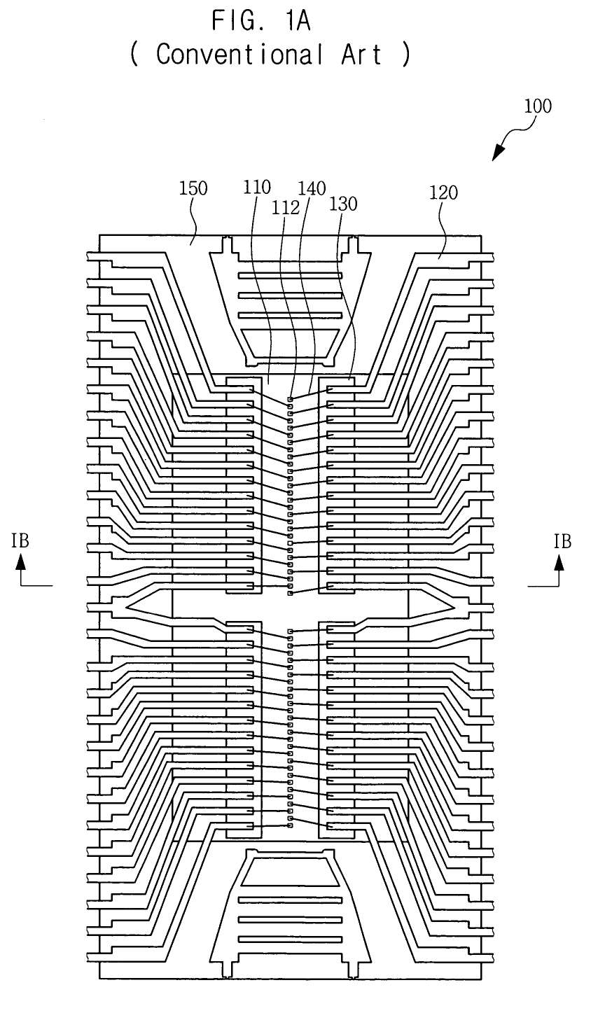

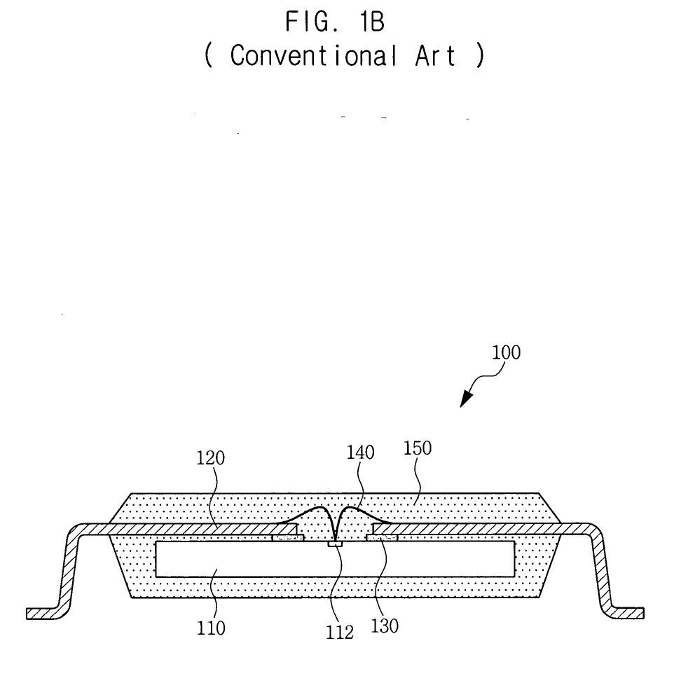

These drawings are provided for illustrative purposes only and are not drawn to scale. The spatial relationships and relative sizing of the elements illustrated in the various embodiments may have been reduced, expanded or rearranged to improve the clarity of the figure with respect to the corresponding description. The figures, therefore, should not be interpreted as accurately reflecting the relative sizing or positioning of the corresponding structural elements that could be encompassed by an actual device manufactured according to the example embodiments of the invention.

### DETAILED DESCRIPTION OF EXAMPLE EMBODIMENTS OF THE INVENTION

Hereinafter, certain non-limiting example embodiments of leadframes and leadframe packages according to the invention will be described in more detail with reference to the accompanying drawings. The various embodiments illustrated herein are intended to assist those skilled in the relevant art in understanding and practicing the invention without difficulty or undue experimentation, but are not to be understood as limiting the scope of the invention. In the description, some structures or processes are not described or drawn in detail because such descriptions would tend obscure the invention in unnecessary detail that is unnecessary for the understanding of those skilled in the art. Similarly, in the drawings, certain conventional elements may be omitted, reduced, exaggerated or only outlined in brief and the same reference symbols and/or numerals are used to identify the same or corresponding elements in the drawings to allow those skilled in the art to appreciate the invention more readily.

As discussed above, a chip pad formed on a semiconductor chip may typically be classified as either a signal pad or a fixed voltage pad according to its function. For example, chip pads connected to a control terminal, an address terminal and/or a data input/output terminal will typically be classified as signal pads while chip pads connected to a power terminal or a ground terminal will typically be classified as a fixed voltage pad. The leads and bonding wires electrically connected to the chip pads will typically be classified according to the chip pad to which they are connected.

In a leadframe package, an electrical connection between a semiconductor chip and an outside system is typically formed by a combination of a lead and a bonding wire. The width of the leads is typically greater than the diameter of the bonding wire, and in the case of an LOC package, the distance between the lead and the active surface of the semiconductor chip is typically less than the distance between the bonding wire and the active surface. Accordingly, in such an electrical connection structure, the lead will typically exhibit relatively high capacitance and low inductance while the bonding wire will typically exhibit relatively low capacitance and high inductance.

In leadframe packages, a signal connection configuration providing lower capacitance will tend to be better suited for high speed operation while a fixed voltage connection configuration providing lower inductance and higher capacitance will tend to reduce noise during high speed operation. Accordingly, leadframes according to example embodiments of the invention reduce the capacitance of the signal connections by reducing the relative lengths of the signal leads and simultaneously reduce the inductance and increase the capacitance of the fixed voltage connection by reducing the relative lengths of the fixed voltage bonding wires and increasing the length and/or width of the corresponding fixed voltage lead.

### First Example Embodiment

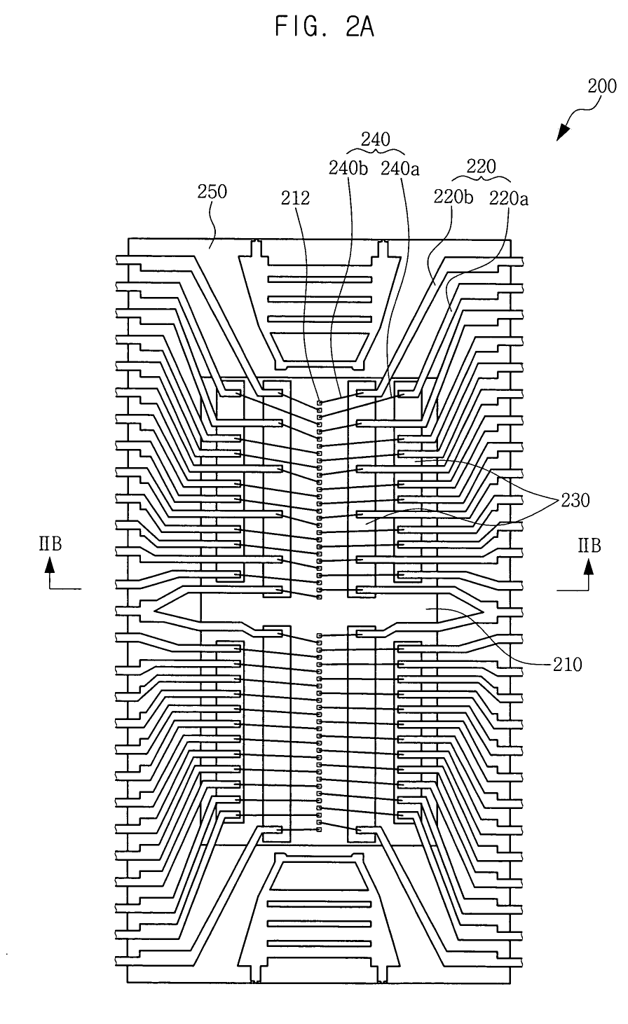

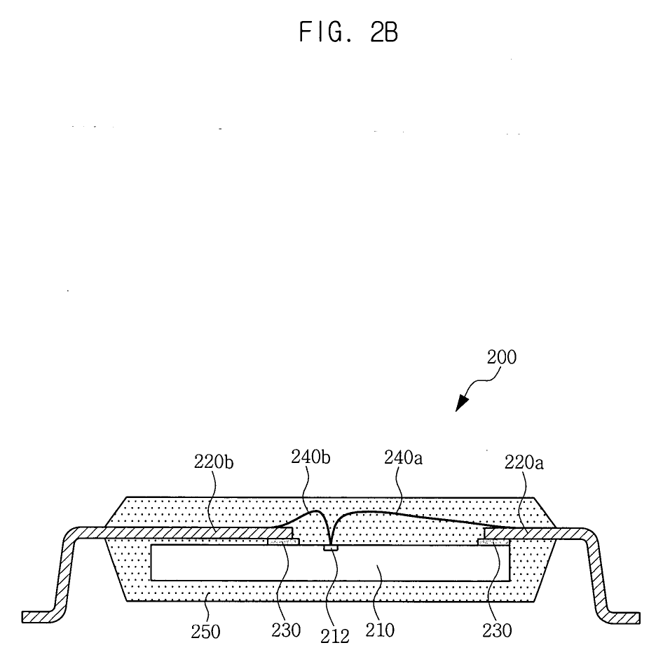

FIG. 2A is a plan view of a leadframe package 200 according to a first example embodiment of the present invention. FIG. 2B is a cross-sectional view of FIG. 2A taken along the line IIB-IIB (that is, cut along a plane running through the length of a lead 220). As illustrated in FIGS. 2A and 2B, the package 200 according to a first example embodiment is an LOC type package with leads 220 extending over portions of the active surface of semiconductor chip 210. In this example embodiment, the leads 220 are attached to the active surface of the semiconductor chip by strips or regions of adhesive 230, for example, adhesive tape.

A plurality of chip pads 212 are aligned in a single row generally along a central longitudinal axis of the active surface of the semiconductor chip 210, with leads 220 generally disposed on either side of the axis and extending across the active surface of the semiconductor chip and towards the chip pads 212. Each of the chip pads 212 is individually electrically connected to a corresponding one of the leads 220 with a bonding wire 240. The semiconductor chip 210, leads 220 and bonding wires 240 are sealed and encapsulated within a molding resin 250 to protect the semiconductor chip and the connections from damage and contamination.

As illustrated in FIGS. 2A and 2B, the average length of signal leads 220a is less than the average length of fixed voltage leads 220b. In addition, the average area of the signal leads 220a extending over the active surface of the semiconductor chip 210 is less than the average area of the fixed voltage leads 220b. As a result of the reduced length of the signal leads 220a, the average distance between the inner ends of the signal leads 220a and their corresponding chip pads 212 will be greater than the average distance between the inner ends of the fixed voltage leads 220b and their corresponding chip pads 212.

As a result of the spacing between the inner ends of the leads 220a, 220b, the average length of the signal bonding wires 240a will be greater than the average length of the fixed voltage bonding wires 240b. The reduced area of the signal leads 220a also reduces the associated capacitance, thereby improving signal delivery characteristics of the signal leads. Conversely, reducing the average length of the fixed voltage bonding wires 240b decreases their relative contribution to the inductance of the connection while increasing the average area leads to a corresponding increase in the capacitance. This combination of reduced inductance and increased capacitance results in fixed voltage connections that exhibit reduced noise.

Characteristics of the electrical connections according to a first example embodiment of a leadframe according to the invention will typically include:

Chip pads aligned in a single, centrally located row;

Average length of the leads that satisfy the relationship: signal lead<fixed voltage lead (L_{SL}<L_{FL});

Average length of the bonding wires that satisfy the relationship: signal wire>fixed voltage wire (L_{SW}>L_{FW});

Average connection length, i.e., the sum of the length of a lead and the length of the corresponding bonding wire, that satisfy the relationship: (signal lead+signal wire)≈(fixed voltage lead+fixed voltage wire)(L_{SL}+L_{SW}≈L_{FL}+L_{FW}), i.e., the average connection length of the signal and fixed voltage paths varies by less than 10%; and/or

Both the signal leads and the fixed voltage leads include regions that extend across a portion of the active surface of the semiconductor chip.

### Second Example Embodiment

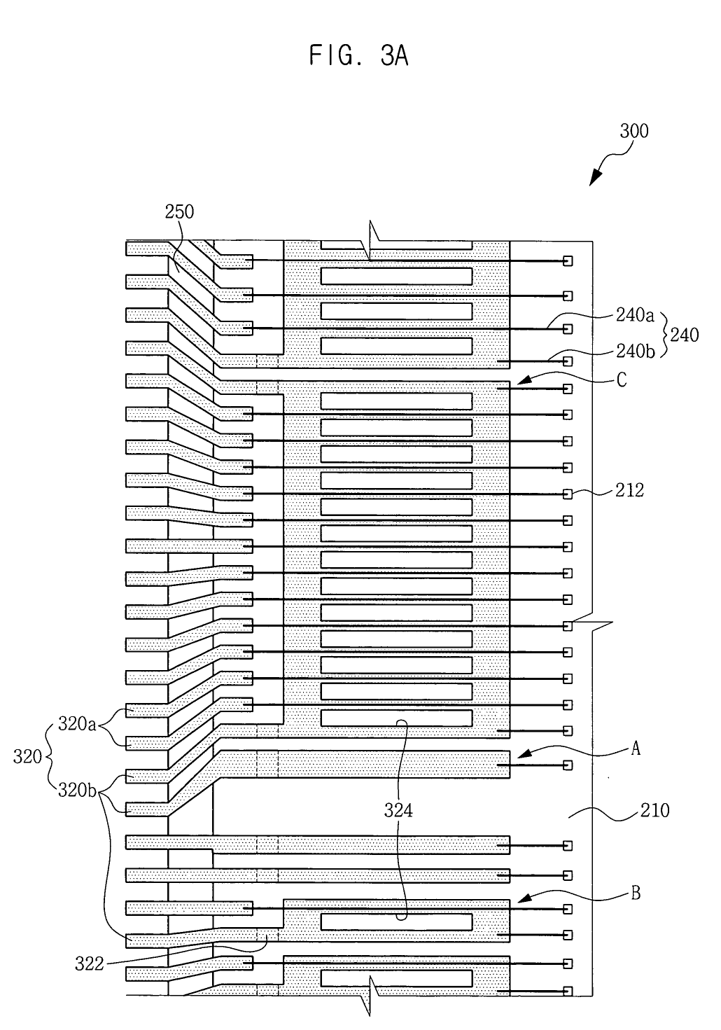

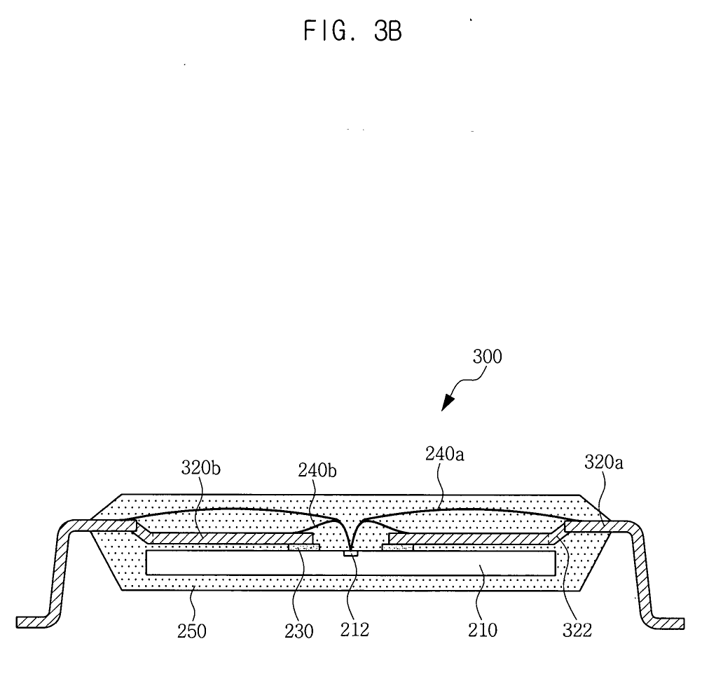

FIGS. 3A and 3B illustrate, respectively, a plan view and cross-sectional view of a leadframe package 300 according to a second example embodiment of the present invention. FIG. 3A illustrates a portion of the package 300 extending from an axis adjacent and parallel to the central longitudinal axis along which chip pads 212 are aligned along the active surface of the semiconductor chip and the outer periphery of the semiconductor chip 210. FIG. 3B illustrates a cross-sectional view taken along a plane extending along the length direction of a lead 320 as generally suggested in FIG. 2B. One or more regions of adhesive tape as described above in connection with FIG. 2A according to a first example embodiment of the invention are omitted from FIG. 3A in the interest of clarity and to reduce the complexity of the drawing but are reflected in FIG. 3B as element 230.

As illustrated in FIGS. 3A and 3B, the package 300 according to a second example embodiment has a characteristic in the configuration of fixed voltage leads 320b. With respect to those components that are identical or similar to those described in connection with the first example embodiment, identical reference numerals will be used and the corresponding explanations will be omitted in the interest of brevity and clarity.

The fixed voltage leads 320b according to a second example embodiment have a relatively large average length and average width when compared with a corresponding signal lead 320a. Increases in the width of the fixed voltage lead 320b may be achieved using one or more various methods including, for example, increasing the width of the fixed voltage lead (as indicated by lead “A” in FIG. 3A) and/or expanding the width of front and/or rear regions of the signal leads 320a (as indicated by lead “B” in FIG. 3A), or by electrically connecting those of the fixed voltage leads 320b that have the same potential, e.g., power or ground (as indicated by “C” in FIG. 3A). By adopting a leadframe structure according to this example embodiment of the invention, the inductance and resistance of the fixed voltage leads 320b can be reduced, thereby reducing noise and improving the power delivery characteristics of the leads.

As illustrated in FIG. 3B, fixed voltage leads 320b according to this example embodiment of the invention may be configured to extend between an inner portion of a signal lead 320a toward a corresponding chip pad 212. Accordingly, the signal bonding wire 240a used for establishing an electrical connection between signal lead 320a and the corresponding chip pad 212 will tend to extend over and long a fixed voltage lead 320b. This connection structure in which the signal bonding wire extends over and along a corresponding fixed voltage lead produces a two-layer structure as illustrated in FIG. 3B.

As illustrated in FIG. 3B, the separation between the signal bonding wire 240a and the underlying fixed voltage lead 320b can be increases by positioning an inner portion the fixed voltage lead 320b below a plane defined by the outer portions of the leads by, for example, bending a transition or down-set region 322 of the fixed voltage so that the inner portion of the fixed voltage lead is positioned closer to the active surface of the semiconductor chip 210 than the signal lead 320a. This modification to the fixed voltage lead 320b will also tend to increase the capacitance of the lead by decreasing the dielectric thickness between the lead and the active surface.

Depending on the lead sizing and the resolution and precision of the fabrication methods utilized, one or more slits or openings 324 may be provided in those fixed voltage lead 320b that have a sufficiently large width as shown in FIG. 3A. The openings 324 provided in the fixed voltage leads 320b allow the molding resin 250 bond to the underlying material and strengthen the mechanical attachment of the lead to the substrate. Additionally, an identification groove or other identifiable feature (not shown) may be formed in the fixed voltage leads to allow automatic bonding machines to recognize and identify the location of the fixed voltage leads 320b during the wire bonding process.

In addition to one or more of the characteristics of the first example embodiment described above, the characteristics of a second example embodiment according to the invention may also include:

Average width of the leads that satisfy the relationship: signal lead<fixed voltage lead (W_{SL}<W_{FL});

Fixed voltage leads configured to decrease the spacing between the inner portions of the leads and the active surface of the semiconductor chip and position the inner portions of the fixed voltage leads below the level of the signal leads;

Openings, crenulations, slits or holes formed in fixed voltage leads whereby portions of the resin molding compound can be “surrounded” by the lead structure and improve the attachment or fixture of the lead to the substrate; and/or
grooves or other alignment or recognition structures that will allow automated systems, for example, wire bonding equipment, to recognize and differentiate the fixed voltage leads.

### Modified Version of the Second Example Embodiment

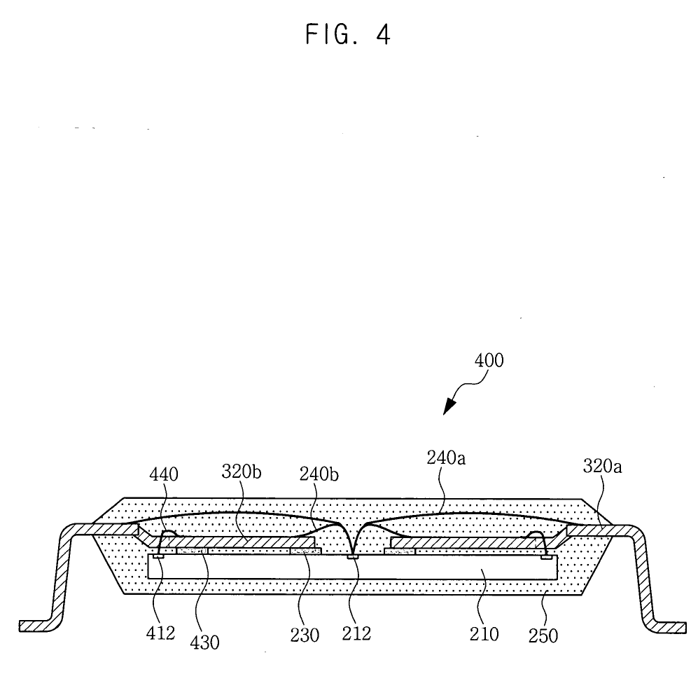

FIG. 4 is a cross-sectional view of an example embodiment of a leadframe package 400 according to a modified version of the second example embodiment of the present invention as detailed above and illustrated in FIGS. 3A and 3B.

As illustrated in FIG. 4, the package 400 has a configuration similar to that described above in connection with the leadframe package according to the second example embodiment. However, the semiconductor chip 210 utilized in the leadframe package 400 includes fixed voltage pads 412 formed in a peripheral region near the edges of the semiconductor chip's active surface in addition to the centrally located chip pads 212. To the extent that the components and/or features of the example embodiments of the leadframe packages 200, 300 illustrated in, for example, FIGS. 2A, 2B, 3A and 3B and described above are similar or identical to those found in leadframe package 400, identical reference numerals will be used and the detailed explanation of these components and/or features will be omitted.

The fixed voltage pads 412 positioned in a peripheral region of the active surface of the semiconductor chip 210 and may supplement and/or replace certain of the fixed voltage pads 212 provided at the center of the active surface of the semiconductor chip and improve the delivery of electric power to the semiconductor chip 210. Although the fixed voltage pads 412 are not centrally located on the active surface of the semiconductor chip 210, they may still be easily connected to the fixed voltage leads using bonding wires 440. When bonding wires 440 are being used to connect the fixed voltage pads 412 and the fixed voltage leads 320b, a supplemental structure of adhesive tape 430 may be provided under fixed voltage leads near the bonding position to improve the ability of the fixed voltage leads to sustain a bonding pressure applied when attaching the bonding wires 440.

### Third Example Embodiment

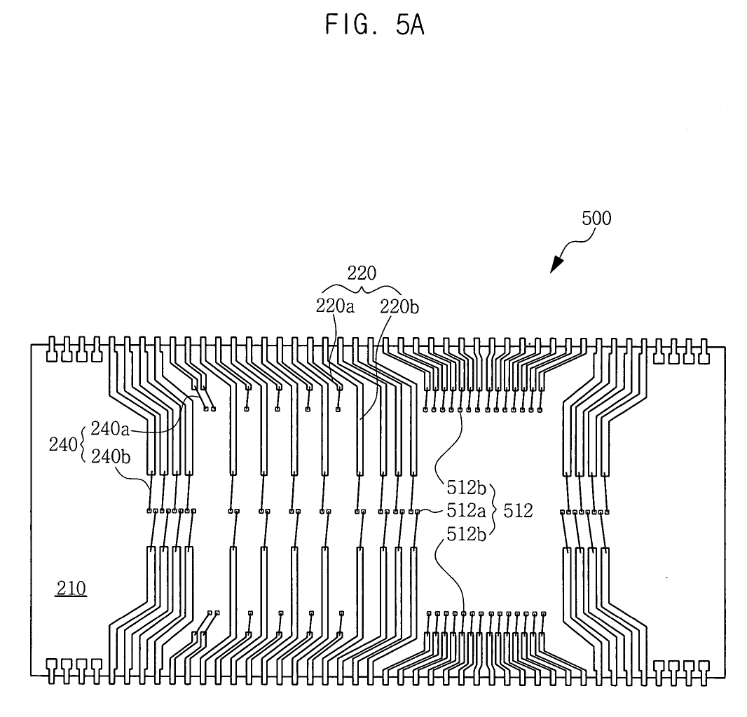

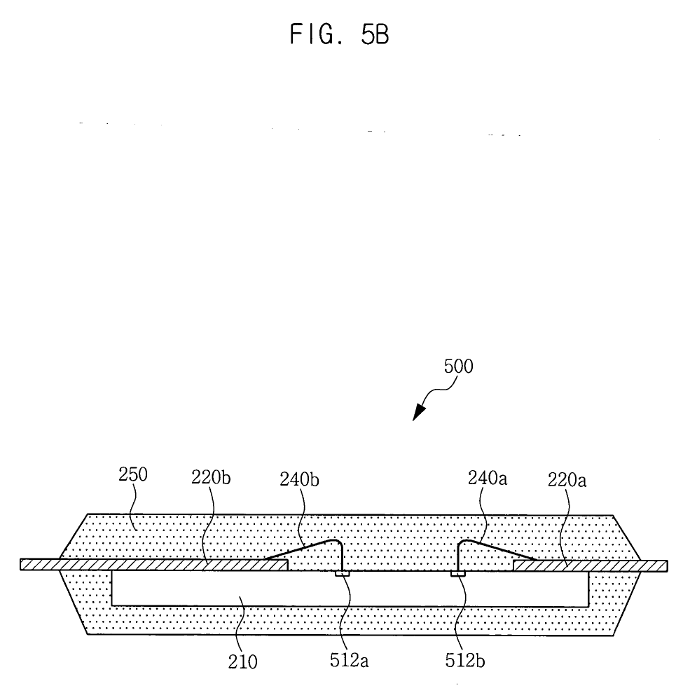

Illustrated in FIGS. 5A and 5B are a plan view and cross-sectional view of a leadframe package 500 according to a third example embodiment of the invention with FIG. 5B representing a cross-sectional view taken along a plane extending in the length direction along a lead 220 as in FIGS. 2B and 3B.

As illustrated in FIGS. 5A and 5B, the package 500 according to a third example embodiment includes chip pads 512 that are not all centrally located on the active surface of the semiconductor chip 210. To the extent that the components and/or features of the example embodiments of the leadframe packages 200, 300 and/or 400 illustrated in, for example, FIGS. 2A, 2B, 3A, 3B and 4 and described above are similar or identical to those found in leadframe package 500, identical reference numerals will be used and the detailed explanation of these components and/or features will be omitted.

The chip pads 512 included in this third example embodiment are configured in three separated longitudinal rows across the active surface of the semiconductor chip 210. First chip pads 512a are provided in a row generally aligned along a central longitudinal axis of the active surface of the semiconductor chip are fixed voltage pads that are, in turn, connected to the fixed voltage leads 220b. Second chip pads 512b are provided in parallel rows aligned with and offset from the central longitudinal axis toward both edges of the active surface of the semiconductor chip and are signal pads that are, in turn, connected to the signal leads 220a.

The configuration of the chip pads 512 may be arranged using conventional technologies relating to wafer level rerouting and wire bonding. The precision and configuration of the wire bonding equipment may lead to the formulation of “design” or “layout” rules that define certain minimum spacing(s) and dimensions for packages assembled on such equipment. For example, the bonding wires 240 as illustrated in FIG. 5A may have a minimum length of 0.75 mm˜1.0 mm which will affect the relative positioning of the ends of the leads and the chip pads to which the leads are to be wire bonded.

In addition to one or more of the characteristics of the first, second and/or modified second example embodiments described above, the characteristics of a third example embodiment according to the invention may also include:

Average length of the bonding wires that satisfy the relationship: signal wire≈fixed voltage wire (L_{SW}≈L_{FW});

Sum of the length of the leads and corresponding bonding wires that satisfy the relationship: signal lead+signal wire<fixed voltage lead+fixed voltage wire (L_{SL}+L_{SW}<L_{FL}+L_{FW}); and/or

Chip pads arranged in parallel rows including a centrally positioned row and at least one row offset from the center row and toward an edge of the active surface of the semiconductor chip.

### Fourth Example Embodiment

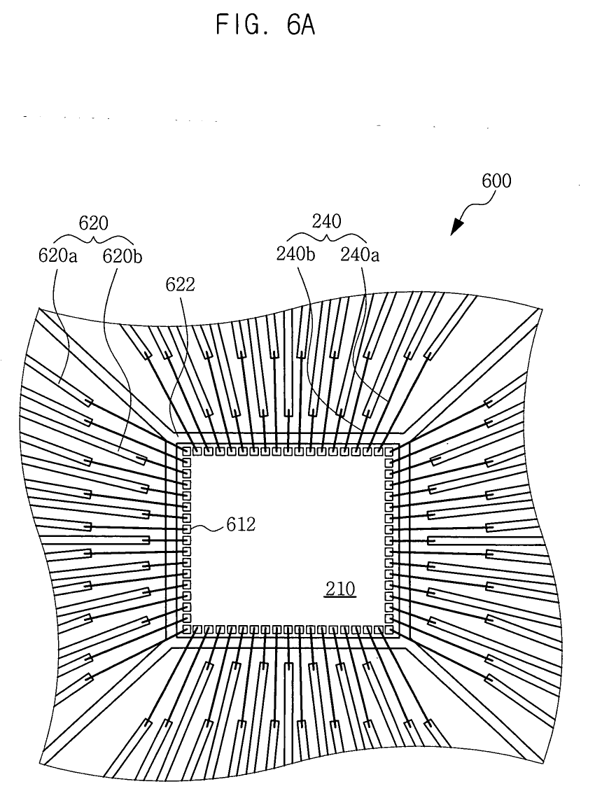

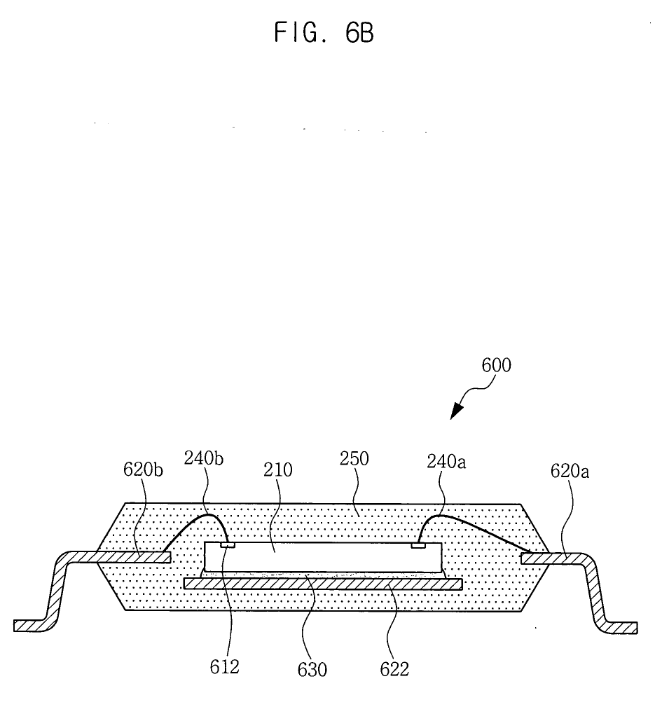

FIGS. 6A and 6B are, respectively, a plan view and a cross-sectional view of a leadframe package 600 according to a fourth example embodiment of the invention. As illustrated in FIGS. 6A and 6B, the leadframe package 600 according to a fourth example embodiment is not an LOC package, but is instead configured as a quad flat package (QFP), another typical configuration used for conventional leadframe packages. As detailed below, certain of the aspects of the invention as described herein may be applied to a range of different leadframe package configurations and are not limited to LOC packages and/or QFP packages.

Leadframe package 600 according to a fourth example embodiment of the invention includes a semiconductor chip 210 attached by an adhesive 630 to an upper surface of a die pad 622 that is a part of the leadframe. None of the various leads 620 extend over any portion of the active surface of the semiconductor chip 210, but the leads are configured to terminate at different distances from the periphery of the semiconductor chip 210. In accord with the configuration of the leads 620, a plurality of chip pads 612 may be provided primarily, or exclusively, in the peripheral region of the active surface of the semiconductor chip 210 along one or more of the edges of the active surface.

Even in leadframe configurations according to the example embodiment illustrated in FIGS. 6A and 6B of the leadframe package 600, the average length of signal leads 620a will typically be less than the average length of fixed voltage leads 620b. Conversely, the average length of signal bonding wires 240a will typically be greater than the average length of the fixed voltage bonding wires 240b. Accordingly, the capacitance of the signal leads 620a, with their relatively small length, will tend to be reduced and thereby improving the signal delivery characteristics of the resulting connection. Similarly, the inductance of the fixed voltage bonding wires 240b, with their relatively small length in combination with the fixed voltage leads 620b, with their relatively large length, will be reduced while the capacitance of the resulting connection is increased. This combination of adjustments to the fixed voltage connection structures, 240b, 620b, tends to reduce noise on the fixed voltage lines and improve the performance of these connections accordingly.

In addition to one or more of the characteristics of the first, second, modified second and/or third example embodiments described above, the characteristics of a fourth example embodiment according to the invention may also include:

Leads configured to avoid extending over any portion of the active surface of the semiconductor chip;

Leads configured to avoid extending over any portion of the active surface of the semiconductor chip other than a peripheral region;

Chip pads located only a peripheral region of the active surface near one or more of the edges of the active surface of the semiconductor chip; and/or

Chip pads located primarily in a peripheral region of the active surface near one or more of the edges of the active surface of the semiconductor chip.

### Fifth Example Embodiment

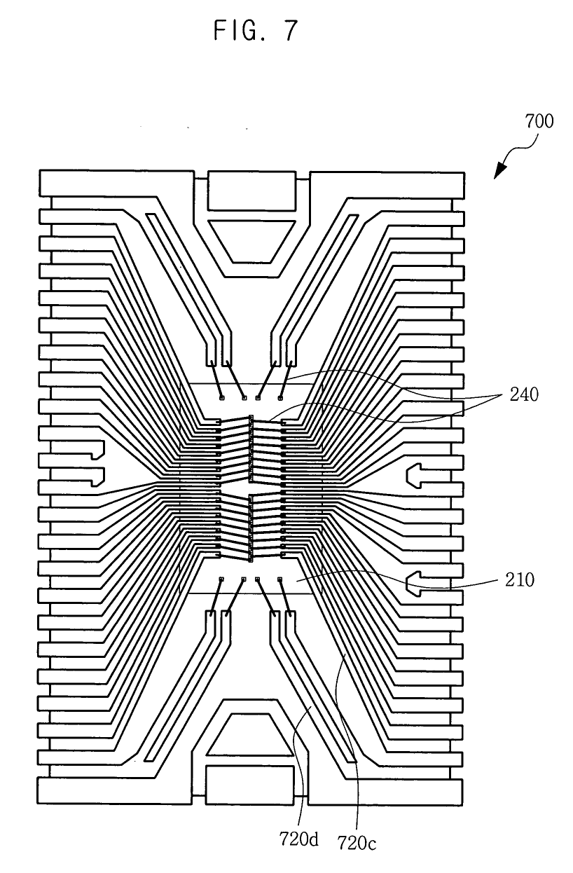

FIG. 7 is a plan view of a leadframe package 700 according to a fifth example embodiment of the present invention. As shown in FIG. 7, a leadframe package 700 according to this fifth example embodiment may be characterized as a hybrid package that incorporates both a style of lead 720c more typically seen in LOC packages and a style of lead 720d more typically seen in a conventional leadframe packages. The “LOC” style leads 720c of the leadframe package 700 may be provided in one or more configurations generally corresponding to the lead configurations described above and illustrated in connection with the first, second or third example embodiments. The “conventional” style leads 720d of the leadframe package 700 may have a lead configuration generally corresponding to that described above in connection with the fourth example embodiment. These two styles of leads 720c, 720d may be utilized for connecting both signal and fixed voltage chip pads by, for example, configuring fixed voltage leads to correspond to the “LOC” lead 720c and configuring the signal leads to correspond to the “conventional” lead 720d.

In addition to one or more of the characteristics of the first, second, modified second, third and/or fourth example embodiments described above, the characteristics of a fifth example embodiment according to the invention may also include:

Chip pads located in both a central region and in one or more peripheral regions of the active surface of the semiconductor chip.

The invention has been disclosed with reference to certain example embodiments as detailed above in this specification and as illustrated in the accompanying drawings. These disclosures are provided for illustrative purposes only and are not intended to, and should not be deemed to, limit the scope of the invention unduly. Persons skilled in the art will understand and appreciate that various changes, modifications and combinations of the example embodiments detailed above, and/or elements of the example embodiments, may be made without departing from the spirit of the invention.

For example, each “row” of the chip pads may include two or more closely spaced rows, may be discontinuous or may include both “single” and “double” row regions. The particular arrangements of the chip pads illustrated in connection with the example embodiments discussed above are illustrative only and should not be considered to limit the range of chip pad arrangements that may be utilized in connection with the invention. Similarly, although the example embodiments of leadframe packages according to the invention described incorporated one semiconductor chip, these configurations were illustrative only and it should be understood that leadframe packages fabricated according to the invention may include multiple semiconductor chips. For example, semiconductor chips may be provided in a stacked configuration and/or may be attached to opposite sides of a single die pad. The semiconductor chip or chips incorporated in a leadframe package according to the invention are not limited and may include one or more types of semiconductor chips selected from a group including, for example, DRAM, SRAM, flash memory and/or system LSI devices.

As described in connection with each of the example embodiments described above, leadframe packages according to the present invention will include a dual lead configuration in which the signal leads and fixed voltage leads are configured to provide differential performance characteristics. For example, the signal leads will typically be configured in a manner that reduces the associated capacitance relative to corresponding fixed voltage leads and thereby improve the high speed performance of the signal leads. Similarly, noise may be reduced and power delivery characteristics may be improved by reducing the inductance and/or resistance of the fixed voltage leads relative to that of corresponding signal leads. Signal delivery characteristics may also be improved by adopting a connector configuration, which may be referred to as a microstrip delivery line, which the signal bonding wires extend over the fixed voltage leads that, in turn, may be offset toward the active surface of the semiconductor chip relative to the signal leads.

Leadframe packages according to the example embodiments of the invention may provide improved lead configurations that adjust the relative intrinsic functions of the leads incorporated in a single leadframe package to improve their performance as either signal leads or fixed voltage leads. The improved lead performance provided by leadframe packages according to the example embodiments of the invention will tend to improve the high speed performance of the resulting semiconductor products.

What is claimed is:

1. A leadframe package comprising:
a semiconductor chip having a plurality of signal chip pads and a plurality of fixed voltage chip pads formed on an active surface;
a leadframe having a plurality of signal leads having an average length L_{SL} and a plurality of fixed voltage leads designated for a single voltage having an average length L_{FL};
signal bonding wires having an average length L_{SW} electrically connecting the signal leads to corresponding signal chip pads; and
fixed voltage bonding wires having an average length L_{FW} electrically connecting the fixed voltage leads to corresponding fixed voltage chip pads;
wherein the average length of the signal leads L_{SL} and the average length of the fixed voltage leads L_{FL} satisfy the expression L_{SL}<L_{FL}.

2. The leadframe package according to claim 1, wherein:
the average length of the signal bonding wires L_{SW} and the average length of the fixed voltage bonding wires L_{FW} satisfy the expression L_{SW}>L_{FW}.

3. The leadframe package according to claim 1, wherein:
the signal leads have an average capacitance C_{SL} and the fixed voltage leads have an average capacitance C_{FL} that satisfy the expression C_{SL}<C_{FL}.

4. The leadframe package according to claim 1, wherein:
the signal leads have an average width W_{SL} and the fixed voltage leads have an average width W_{FL} that satisfy the expression W_{SL}<W_{FL}.

5. The leadframe package according to claim 1, wherein:
the sum of the average length of the signal leads L_{SL} and the average length the signal bonding wires L_{SW} and the sum of the average length of the fixed voltage leads L_{FL} and the average length of the fixed voltage bonding wires L_{FW} satisfy the expression (L_{SL}+L_{SW})≈(L_{FL}+L_{FW}).

6. The leadframe package according to claim 1, wherein:
the sum of the average length of the signal leads L_{SL} and the average length the signal bonding wires L_{SW} and the sum of the average length of the fixed voltage leads L_{FL} and the average length of the fixed voltage bonding wires L_{FW} satisfy the expression (L_{SL}+L_{SW})<(L_{FL}+L_{FW}).

7. The leadframe package according to claim 1, wherein:
all of the signal leads extend over the active surface of the semiconductor chip; and
all of the fixed voltage leads extend over the active surface of the semiconductor chip.

8. The leadframe package of claim 1, wherein:
none of the signal leads extend over the active surface of the semiconductor chip; and
none of the fixed voltage leads extend over the active surface of the semiconductor chip.

9. The leadframe package according to claim 1, wherein:
the signal leads include a first subset of signal leads that extend over the active surface of the semiconductor chip and a second subset of signals leads do not extend over the active surface of the semiconductor chip; and
the fixed voltage leads include a first subset of fixed voltage leads that extend over the active surface of the semiconductor chip and a second subset of fixed voltage leads that do not extend over the active surface of the semiconductor chip.

10. The leadframe package according to claim 1, wherein:
none of the signal leads extend over the active surface of the semiconductor chip, and
all of the fixed voltage leads extend over the active surface of the semiconductor chip.

11. The leadframe package according to claim 1, wherein:
a plurality of the signal leads include an inner portion that extends over the active surface of the semiconductor chip, the inner portions of the signal leads having an average area A_{SL}; and
a plurality of the fixed voltage leads include an inner portion that extends over the active surface of the semiconductor chip, the inner portions of the fixed voltage leads having an average area A_{FL} that satisfy the expression A_{SL}<A_{FL}.

12. The leadframe package according to claim 1, wherein:
a plurality of fixed voltage leads are configured to extend between a major portion of a corresponding plurality of signal bonding wires and the active surface of the semiconductor chip.

13. The leadframe package according to claim 12, wherein:
a plurality of fixed voltage leads include an inner portion that extends over the active surface of the semiconductor chip and is separated from the active surface by an average distance D_{FL}; and
a plurality of signal leads include an inner portion that extends over the active surface of the semiconductor chip and is separated from the active surface by an average distance D_{SL} that satisfy the relationship D_{FL}<D_{SL}.

14. The leadframe package according to claim 1, wherein:
the signal chip pads and the fixed voltage chip pads are arranged in a single row oriented along a central axis of the semiconductor chip.

15. The leadframe package according to claim 1, wherein:
the signal chip pads and the fixed voltage chip pads are arranged in at least one row adjacent an edge of the active surface of the semiconductor chip.

16. The leadframe package according to claim 1, wherein:
a first subset of the signal chip pads and the fixed voltage chip pads are arranged in a first row oriented along a central axis of the semiconductor chip; and
a second subset of the signal chip pads and the fixed voltage chip pads are arranged adjacent an edge of the active surface.

17. The leadframe package according to claim 14, wherein:
all of the signal leads and the fixed voltage leads extend over the active surface of the semiconductor chip and are disposed on both sides of the row of the chip pads.

18. The leadframe package according to claim 17, wherein:
wherein an average distance between the signal leads and corresponding chip pads is greater than that between the fixed voltage leads and the chip pads.

19. The leadframe package according to claim 1, wherein:
a plurality of fixed voltage leads are configured to extend between a corresponding plurality of signal leads and a corresponding plurality of signal chip pads.

20. The leadframe package according to claim 1, wherein:
a plurality of the fixed voltage leads include an opening formed in an enlarged region of the fixed voltage leads.

21. The leadframe package according to claim 1, wherein:
a plurality of the fixed voltage leads include a recess formed inwardly from an edge of an enlarged region of the fixed voltage leads.

22. The leadframe package according to claim 1, wherein:
at least one fixed voltage lead includes an optical pattern recognition target formed in an enlarged portion of the fixed voltage lead.

23. The leadframe package according to claim 1, wherein:
a first group of fixed voltage leads are designated for connection to a power potential and include a first optical pattern recognition target; and
a second group of fixed voltage leads are designated for connection to a ground potential and include a second optical pattern recognition target.

24. The leadframe package according to claim 1, wherein:
a first group of chip pads are arranged in a first row along a central portion of the active surface of the semiconductor chip; and
a second group of chip pads are arranged in a second row positioned between the first row and an edge of the active surface of the semiconductor chip.

25. The leadframe package according to claim 14, wherein:
a first group of fixed voltage leads are designated for connection to a power potential;
a second group of fixed voltage leads are designated for connection to a ground potential; and
at least one of the fixed voltage leads is electrically connected to at least one other fixed voltage lead selected from the same group.
